(19) United States
(12) Patent Application Publication
(10) Pub. No.: US 2026/0018439 A1
(43) Pub. Date: Jan. 15, 2026

(54) CONTACTLESS POSITION MONITOR FOR SEMICONDUCTOR MANUFACTURING EQUIPMENT

(71) Applicant: Shanghai GND eTech Co., Ltd, Shanghai (CN)

(72) Inventors: Zihuan Xia, Shanghai (CN); Chao Lian, Shanghai (CN); Jie Xu, Shanghai (CN); Gaosheng Shi, Shanghai (CN); Duo Wu, Shanghai (CN); Jie Ji, Shanghai (CN); Qiujin Wang, Shanghai (CN)

(73) Assignee: Shanghai GND eTech Co., Ltd, Shanghai (CN)

(21) Appl. No.: 19/242,025

(22) Filed: Jun. 18, 2025

Related U.S. Application Data
(63) Continuation-in-part of application No. 18/767,392, filed on Jul. 9, 2024.
(63) Continuation-in-part of application No. 19/228,685, filed on Jun. 4, 2025.

(51) Int. Cl. H01L 21/67; G01B 11/14

(52) U.S. Cl. CPC H01L 21/67259; G01B 11/14

(57) ABSTRACT

Provided is a system and method for contactless and precise measurement of the system's position relative to a nearby object. The system comprises a workpiece, at least one assembly, and a central control unit. The assembly comprises a main axis directed to a first direction and approximately parallel to the surface of the workpiece to intersect a deflector which is mounted on the workpiece and along the second direction; the deflected portion of the main axis intersects with an object in the third direction. The assembly further comprises at least one projector for projecting an electromagnetic beam onto the object for the measurement. Both the assembly and the central control unit are attached on the surface of the workpiece at desired locations. The entire system is configured to have a low profile and can be operated stand alone in an enclosed and dimensional constrained operation environment.

### CROSS-REFERENCE TO RELATED APPLICATIONS

The present application is a Continuation-In-Part application of U.S. patent application Ser. No. 18/767,392 filed Jul. 9, 2024 and U.S. patent application Ser. No. 19/228,685 filed Jun. 4, 2025, the entire contents of which are incorporated herein by reference.

### BACKGROUND OF THE INVENTION

The present invention relates generally to methods and systems for contactless object measurement, more particularly to a low-profile contactless position monitor for semiconductor processing system.

Semiconductor fabrication involves the intricate patterning and deposition of materials on wafer surfaces, with dimensional tolerances often measured in nanometers. To achieve such precision and ensure high yield, stringent requirements for equipment calibration, alignment, and accurate positioning of the semiconductor substrate must be met.

As an example of precise alignment and position control in semiconductor fabrication, FIGS. 1A through 1D illustrate a plasma dry etching system. The dry etching process is used to pattern thin films on semiconductor wafers, which are typically positioned at the center of the etching stage. Unlike wet etching, which employs liquid chemicals to remove material, dry etching removes material through physical or chemical interactions in a gaseous phase, usually within a vacuum chamber.

In the system 100 shown in FIGS. 1A-1D, a mixture of reactive gases is introduced into the chamber via a showerhead located on the upper electrode 112. Radiofrequency (RF) energy, supplied by an RF power network, is applied between the upper electrode and the lower electrode 116 to generate a plasma that ionizes the gases. The resulting ions bombard the wafer surface, breaking chemical bonds and removing material. The etch selectivity and profile can be tuned by controlling the gas chemistry and process parameters such as chamber pressure and RF power.

To improve etching uniformity near the wafer edge, a focus ring 122 is positioned on the wafer chuck atop the lower electrode 116, which also serves as the substrate holder. As depicted in FIGS. 1A and 1B, the semiconductor wafer 120 is placed concentrically within the focus ring. From the side view (FIG. 1C, x-z plane), the top surface of the focus ring 122 is approximately level with the surface of the wafer 120 with a small height difference 126, typically about 1 mm. This alignment ensures that the electric field above the focus ring closely matches that above the wafer surface, thereby minimizing discontinuities in bias potential caused by fringing effects. Consequently, the plasma sheath forms at a uniform height over both the wafer and the focus ring, allowing incident ions to strike the wafer surface perpendicularly, even at its periphery.

Such an arrangement enhances etch uniformity across the wafer. To be effective, however, the wafer and focus ring must be precisely aligned concentrically. Any deviation from this alignment introduces fringing effects, leading to nonuniform etching near the wafer edge (see, for example, U.S. Pat. No. 7,658,816 and U.S. Patent Application Publication No. 2023/0402255).

Another example of precise alignment and position control for maximizing yield in semiconductor fabrication is maintaining the top electrode, also referred to as the showerhead (112), parallel to the surface of the substrate. If the plane of the substrate surface and the plane of the showerhead are not parallel, the resulting flux of ions and radicals will be nonuniform across the wafer surface, leading to inconsistent etching results. Therefore, it is critical during the setup of a semiconductor processing tool to ensure that the showerhead and the substrate (or the substrate holder positioned above the lower electrode) are properly aligned in parallel. Achieving this requires the capability to periodically measure the distance (130) from the showerhead to the substrate at multiple points, ensuring that the spacing is consistent across the entire substrate surface.

Breaking the chamber's vacuum environment to measure the distance between the showerhead and the substrate is undesirable. U.S. Pat. No. 7,893,607 addresses this challenge by enabling contactless distance measurement. The patent discloses a wafer-like device that includes multiple pairs of capacitive plates arranged to form capacitors whose capacitance varies with the distance to the showerhead. The device is equipped with a power source, wireless communication circuitry, a controller, and measurement circuitry. This circuitry measures capacitance at various locations across the device, enabling the system to determine whether the showerhead is parallel to the surface of the sensing device.

This wafer-like sensing device offers several advantages. It can be handled by the system's wafer-handling robot and introduced directly into the processing chamber, enabling in-situ monitoring under actual processing conditions. It also allows automated measurements at multiple locations to assess the parallelism between the substrate and the showerhead. The results from these measurements can then be used to adjust the showerhead or substrate holder, promoting uniform processing.

However, despite its convenience and compatibility with the processing environment, the capacitive sensing device is sensitive to surrounding electromagnetic fields. This sensitivity can compromise measurement accuracy and lead to poor repeatability.

### SUMMARY OF THE INVENTION

According to aspects illustrated here, provided are a contactless system and method to precisely determine a gap between a workpiece and an object. More particularly, provided is a stand-alone system which can be operated in an enclosed and dimensional constrained environment. Furthermore, provided is a system capable of measuring the gap between the surface of a workpiece and an object above it.

In various aspects, the present disclosure provides a contactless system comprising a workpiece, at least one assembly, and a central control unit. The control unit comprises a power source and an image processor. The control unit and the assembly are attached to a surface of the workpiece.

In various aspects of the present invention, the assembly comprises a main axis directed to a first direction and approximately parallel to the surface of the workpiece to intersect a deflector which is mounted on the workpiece and along the second direction; the deflected portion of the main axis intersects with an object in the third direction.

In various aspects of the present invention, the assembly further comprises at least one projector for projecting an electromagnetic beam toward the deflector, wherein the beam is configured to intersect with the main axis at a reference plane either before or after the deflection; the projection of the beam produces a beam spot on a surface of an object; the separation between the spot and the main axis along a second direction is proportional to the distance from the surface of the object to the reference plane.

In various aspects of the present invention, alternatively, the assembly includes a first and a second projectors mounted on the workpiece for projecting electromagnetic beams toward the deflector, wherein the first and the second beams are configured to be symmetrical about the main axis and to intersect with each other at a reference plane either before or after the deflection; the deflected first and second beams produce a first and second beam spots on the surface of an object; the separation between the first and second beam spot along a second direction is proportional to the distance from the surface of the object to the reference plane.

In various aspects of the present invention, the assembly further comprises a focusing element centered on the main axis for focusing the reflected beam of the spot from the object surface, and forming an image of the spot on an image plane.

In various aspects of the present invention, the assembly further comprises an imaging sensor array placed at the image plane and coupled with the image processor in the control unit to determine the position of the image of the spot on the image plane, and to derive the gap between the surface of the workpiece and the surface of the object above the workpiece.

In various aspects of the present invention, the entire system is configured to have a low profile, with all beam paths constrained within the system's overall height in a third direct.

In one embodiment, the deflection angle of the deflector is adjustable to deflect a beam to a desired direction.

In various aspect of the present invention, the contactless system comprises at least three of the assemblies which are attached on the workpiece and aligned their main axis to different directions to detect the gap between the surface of the workpiece and the surface of the object in the third direction at different positions on the workpiece.

### BRIEF DESCRIPTION OF DRAWINGS

A more complete appreciation of the invention and many of the attendant advantages thereof will be readily obtained and understood by referring to the following detailed description and the accompanying drawings in which like reference numerals denote like elements as between the various drawings. The drawings, briefly described below, are not to scale.

FIG. 1A-1D illustrate a prior art semiconductor plasma processing chamber.

FIG. 2A and FIG. 2B are illustrations of a system for contactless object measurement according to some embodiments of the present disclosure.

FIG. 3A is a perspective view of a portion of an assembly and FIG. 3B is a ray tracing diagram of the assembly according to some embodiments of the present disclosure.

FIG. 4A-4C illustrate various relationships between object surface, reference plane, and the surface of a workpiece for the assemble shown in FIG. 3B.

FIG. 5A and FIG. 5B illustrate beam spot on an imaging sensor arrays at the image plane according to some embodiments of the present disclosure.

FIG. 6A is a perspective view of a portion of an assembly and FIG. 6B is a ray tracing diagram of the assembly according to some embodiments of the present disclosure.

FIG. 7A-7E illustrate various relationships between object surface, reference plane, and the surface of a workpiece for the assemble shown in FIG. 6B.

FIG. 8A and FIG. 8B illustrate beam spot on an imaging sensor arrays at the image plane according to some embodiments of the present disclosure.

FIG. 9 illustrates one configuration of the assembly according to some embodiments of the present disclosure.

FIG. 10 is a cross-section view, illustrating a system for contactless object measurement according to some embodiments of the present disclosure.

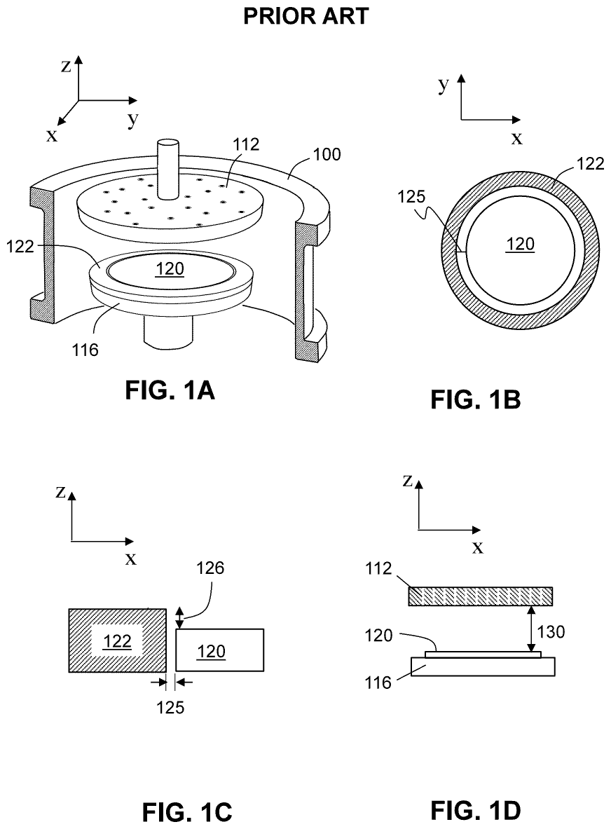

### DETAILED DESCRIPTION OF THE INVENTION

In the following detailed description of the embodiments of the invention, numerous specific details are set forth in order to provide a thorough understanding of the embodiments of the invention. However, it will be obvious to one skilled in the art, that the embodiments of the invention may be practiced without these specific details. In other instances well known methods, procedures, components and circuits have not been described in detail so as not to unnecessarily obscure aspects of the embodiments of the invention.

Furthermore, it will be clear that the invention is not limited to these embodiments only. Numerous modifications, changes, variations, substitutions and equivalents will be apparent to those skilled in the art, without parting from the spirit and the scope of the invention.

One objective of the present invention is to provide a low-profile contactless system and method for precisely determining the distance between a workpiece and an above object such as distance 130 between a showerhead of a semiconductor processing chamber and wafer 120. In order for the system to accommodate existing wafer fabrication environment, the overall height is configured to have a low profile. In one embodiment, the dimension of the low-profile is 10 mm. In an alternative embodiment, the dimension of the low-profile is 6 mm. In a preferred embodiment, the dimension of the low-profile is 3-4 mm. The system can be operated stand-alone in a dimensional constrained operation environment, such as in a semiconductor processing chamber and handled by a robot.

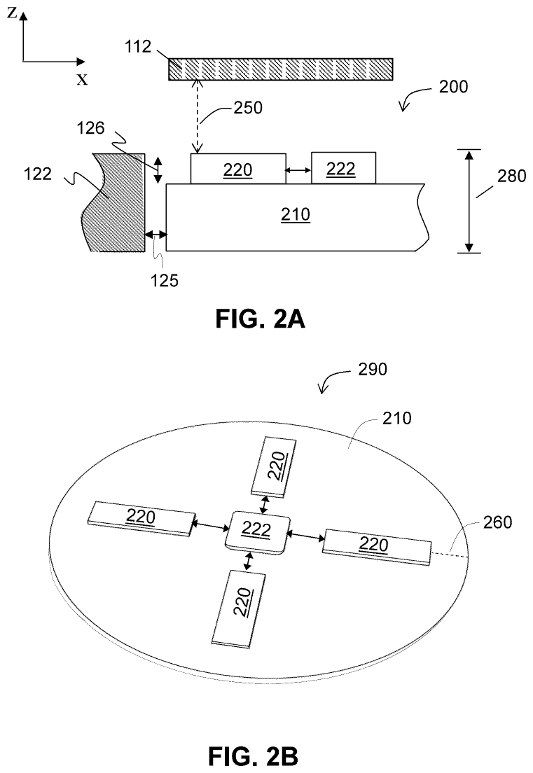

With reference to FIGS. 2A, the contactless object measurement system 200 comprises a workpiece 210, at least one assembly 220, and a central control unit 222. The control unit may include an image processing electronics, data storage memory, and a power source. The control unit may also include data communication electronics for wired or wireless communication. The power source in the control unit is responsible to power various components in the system 200. In one embodiment, the power source is a battery such as a primary or rechargeable battery, wherein the rechargeable battery may be charged by an external power supply with a cable connection, or it can be charged remotely such as with an RF power source or a light source.

The assembly 220 projects electromagnetic beams 250 toward the above object such as showerhead 112 to measure the distance between the showerhead and the workpiece in z-axis direction. The diameter of the beam spot is smaller than 1 mm. Both the assembly 220 and the central control unit 222 are attached on the surface of the workpiece 210 at desired locations.

For clarity in describing the system configuration, a right-handed Cartesian coordinate system (x, y, z) is used. The first, second, and third directions are defined as the directions along the x-axis, y-axis, and z-axis, respectively.

In one embodiment, the workpiece 210 is a wafer or wafer-like substrate, such as a semiconductor wafer, a ceramic wafer, or any other materials in a wafer form. The thickness of such wafer depends on the size (diameter) of the wafer. For example, a typical thickness of a 12-inch silicon wafer is 0.775 mm. In a typical semiconductor processing environment, automated robot handling requires a clear zone near the wafer edge for robot grabbing and positioning the wafer. The robot system utilizes an area near the wafer edge to examine the condition of a loaded wafer. This is done to verify the wafer's integrity and to ensure that only one wafer is present at a given location. Therefore, the workpiece thickness in the clear zone should be approximately equal to the wafer thickness. The assembly 220 and the central control unit 222 should be mounted with a clearance from the wafer edge to avoid interference during wafer inspection by the robot system. As an example, the clearance may be greater than 1 mm.

Another restriction for system 200 is the maximum height 280 in z-direction. For a batch processing system, the distance between each wafer in z-axis is about 3-6 mm. In other application environment, the space above a wafer may be smaller than 4 mm. For this reason, the system 200 including assembly 220 and the central control unit 222 are constructed to be low-profile, such as within 6 mm height in z-direction, preferably less than 3 mm, so that the entire system 200 can fit into a typical wafer operation environment. The combination of the restriction of height and maintaining a clear zone near the edge of a wafer defines the dimensional constrain for the contactless measurement 200. Various embodiments of constructing a low-profile assembly will be described in details in the following descriptions.

According to some embodiments of the present invention, the low-profile contactless system 200 may include multiple assemblies 210 to measure the distance between the showerhead and the workpiece at various locations. In one embodiment, three assemblies may be arranged to measure the distance between the showerhead and the surface of the workpiece to determine whether the workpiece is parallel to the showerhead. In another embodiment, four assemblies may be used to measure the distance between the showerhead and the workpiece in four directions. FIG. 2B is a perspective view of system 290 in which four assemblies 220 are mounted on the workpiece 210 to measure the distance between the showerhead and the workpiece at four different locations and to determine whether the showerhead is parallel to the workpiece.

According to some embodiments of the present invention, assembly 220 compresses at least one beam projector, a deflector, a focusing element, and an image sensor.

The projector projects an electromagnetic beam which is characterized by a wavelength spectrum selected from visible light, microwave, infrared light, and ultraviolet light. For example, the projector can be a solid state light source such as a semiconductor laser or LED device. Alternatively, an incident beam can be constructed by an optical fiber coupling to a light source.

According to some embodiments of the present invention, the assembly 220 may also include a focus element such as a focus lens having a variable focus length or having a larger depth of field for clear image formation.

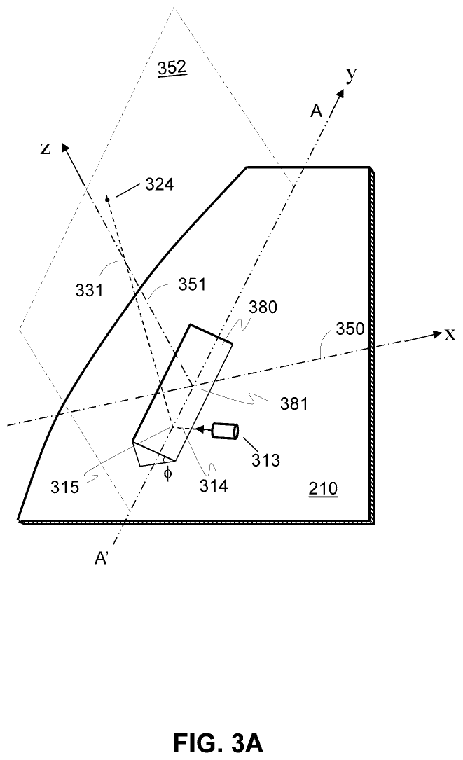

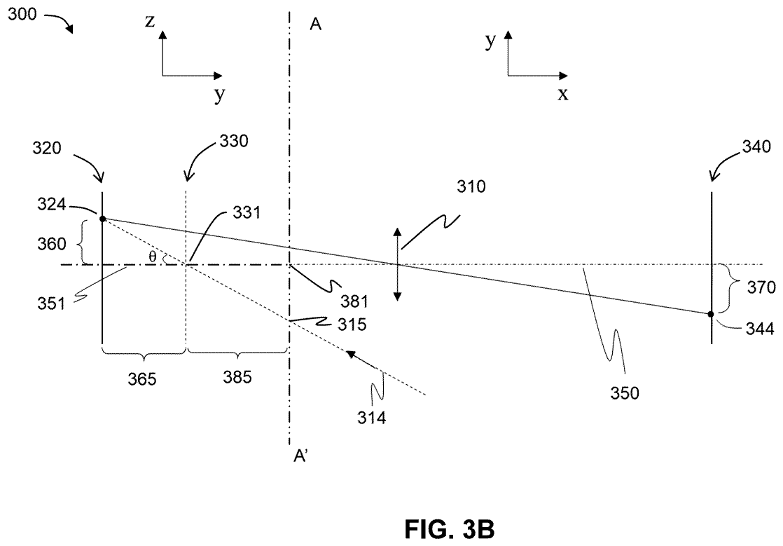

FIG. 3A and FIG. 3B provide an example of the low-profile assembly 220 according to one embodiment of the present invention. FIG. 3A is a perspective view of a portion of assembly 220. The assembly has a main axis 350, which defines the center of symmetry of the assembly and lies along the x-direction. The main axis 350 can be viewed as a virtual beam which intersects with a beam deflector 380, which is placed along the line AA′ at location 381 at y direction. In one embodiment, the surface of the deflector 381 has a 45° rotation angle (ϕ) around y-axis and it deflects the main axis toward z-direction (portion 351). A projector 313 is placed on the workpiece and it projects a beam 314 to intersect with the deflector at location 315. The deflected beam intersects with the z axis (deflected portion 351 of the main axis) at location 331 and form a beam spot 324 on the surface of the showerhead (not shown here).

To aid in explaining the assembly's operation, FIG. 3B folds portion 352 of the y-z plane at the AA′ line onto the x-y plane, facilitating analysis of beam paths on a flat surface. As shown in FIG. 3B, on the right side of the AA′ line, the main axis 350 is directed along a first direction (x-axis), approximately parallel to the surface of the workpiece 210. On the left side of the AA′ line, the main axis 351 continues on y-z plane, and intersects the showerhead surface 320. The projector 313 projects an electromagnetic beam 314 onto the deflector 380 at location 315, and the beam continues its path on y-z plane. The beam intersects with the main axis 351 at location 331 on a reference plane 330, and produces a beam spot 324 on the surface of the showerhead 320. The distance 365, d₃₆₅, from the showerhead surface 320 to the reference plane 330 along x-axis is proportional to d₃₆₀ which is the separation between the beam spot 324 and the main axis 351 along z-axis:

d₃₆₅=d₃₆₀×cotθ, where θ is the angle between the main axis 350 and the incident beam 314. cot θ can be obtained by a calibration from a set of known d₃₆₅ and d₃₆₀.

The distance 385, d₃₈₅, which is the distance between the reference plane 330 and the AA′ line 315, is related to the arrangement of the beam projector 313, and is therefore known once the system is built. The distance between the surface of the showerhead and the surface of the workpiece is the sum of d₃₆₅ and d₃₈₅.

With continued reference to FIG. 3B, the incident beam 314 is reflected by the showerhead at spot 314, and then deflected by the deflector 380 to x-y plane at the AA′ line. The assembly 300 further comprises a focusing element 310, such as a focusing lens, centered on the main axis. This element focuses the beam reflected and then deflected from the spot 324 on the showerhead surface, forming an image of the spot 344 on an image plane 340. The separation 370, d₃₇₀, between the image spot 344 and the main axis 350 along y-axis is proportional to the separation 360, d₃₆₀, and in turn is proportional to the distance 365, d₃₆₅. Therefore, d₃₆₅ can be determined according to d₃₇₀.

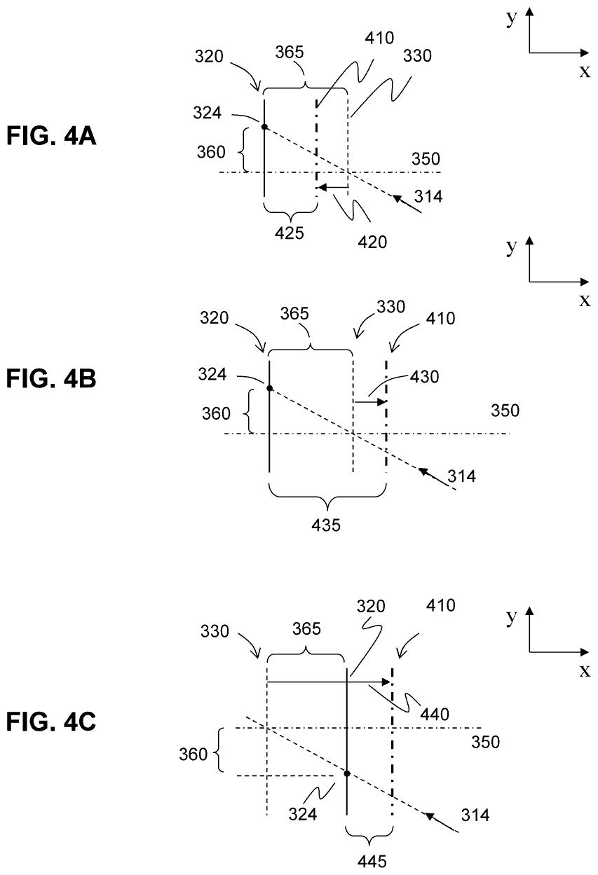

With reference to FIG. 3B, FIG. 4A-4C illustrate various relationships between the showerhead surface 320, the reference plane 330, and the surface of the workpiece for the assembly 300 shown in FIG. 3B.

Shown in FIG. 4A, on the “flat surface” of FIG. 3B, the wafer (represented by the AA′ line) is located between the showerhead surface 320 and the reference plane 330. This is a scenario in which beam 314 crosses the main axis 350 before intersecting deflector 380. The incident beam 314 forms beam spot 324 which is above the main axis in y-direction. The gap 425 between the surface of the wafer and the showerhead surface equals to d₃₆₅−d₄₂₀.

In FIG. 4B, the wafer surface 410 is positioned to the right of both the showerhead surface 320 and the reference plane 330, where beam 314 crosses the main axis 350 after intersecting deflector 380. The incident beam 314 forms beam spot 324 above the main axis in y-direction. The gap 435 between the surface of the wafer and the surface of the showerhead equals to d₃₆₅+d₄₃₀.

In FIG. 4C, both showerhead surface 320 and the surface of the workpiece 410 are located on the right side of the reference plane 330. The incident beam 314 forms beam spot 324 below the main axis 350 in y-direction. The gap 445 between the surface of the wafer and the surface of the showerhead equals to −d₃₆₅+d₄₄₀.

In view of above three cases, we may have a general equation calculating the gap between the surface of the wafer and the surface of the showerhead:

$$gap = {d}_{swh} + {d}_{ref} \qquad ( 1 )$$

where d_{swh} (d₃₆₅) is the distance from the surface of the showerhead 320 to the reference plane 330, and d_{ref} is the distance from the reference plane to the surface of the wafer. When the beam spot 324 is below the main axis 350 in y-direction, the showerhead surface 320 is on the right of the reference plane 330 and d_{swh} is negative, as shown in FIG. 4C. When the reference plane 330 is on the right of the surface 410 of the wafer, d_{ref} is negative, as shown in FIG. 4A. Under the condition that the reference plane 330 is at the surface 410 of the wafer, gap=d_{swh}.

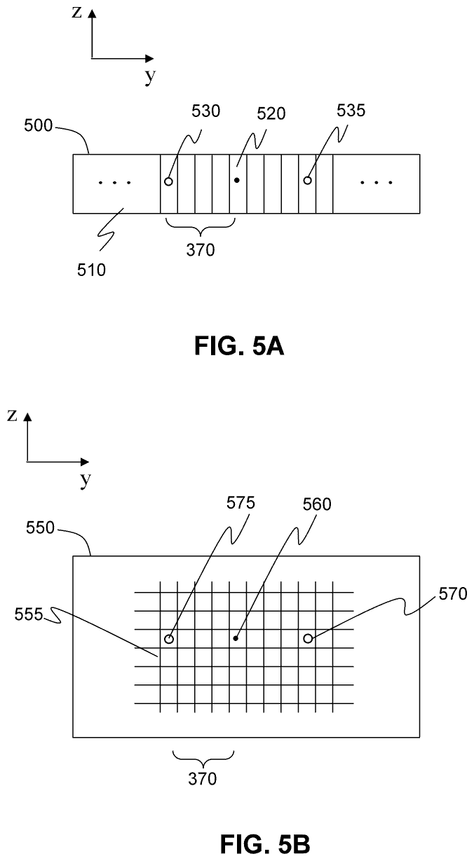

Referring now to FIGS. 5A and 5B, in view of FIG. 3, assembly 300 includes an imaging sensor array placed at the image plane 340 (y-z plane). FIG. 5A shows a linear image array 500, comprising a plurality of imaging pixels 510 arranged in y-direction on y-z plane. The main axis 350 of assembly 300 intersects the image array 500 at location 520. The image spot 344, reflected from the showerhead surface 320, which may not be perfectly mirror-like, is detected by the imaging sensor array at location 530. Due to the non-ideal reflective properties of the showerhead surface, the reflected image spot on the image plane 340 appears as a distribution rather than a sharp point. The center of the image spot can be determined using either geometric analysis or intensity-weighted centroid estimation. In geometric analysis, the spot center is identified as the center of the distribution. In intensity-weighted centroid estimation, the center is calculated as the intensity-weighted average of the pixel positions. These optical image analysis methods are well known in the field and will not be discussed in further detail here.

The distance 370 between location 520 and 530 is proportional to the value of d_{swh}. As described above, the reference plane 330 can be on the left side of the showerhead surface 320 in FIG. 4C, and the beam spot 324 is below the main axis 350 in y-direction. Under this condition, the image spot location 535 is on the right side of location 520, and d_{swh} is negative.

FIG. 5B shows a 2-dimensional image array 550, comprising a plurality of imaging pixels 555 arranged in y-z plane. The main axis 350 of assembly 300 intersects the 2-dimensional image array 550 at location 560, and the image spot 344 is detected by the imager at location 570 or 575 depending on the location of the reference plane 330 relative to the showerhead surface 320.

According to an alternative embodiment of the present invention, a low-profile assembly 220, shown in FIGS. 2A and 2B, may include two projectors that emit electromagnetic beams to enhance measurement accuracy.

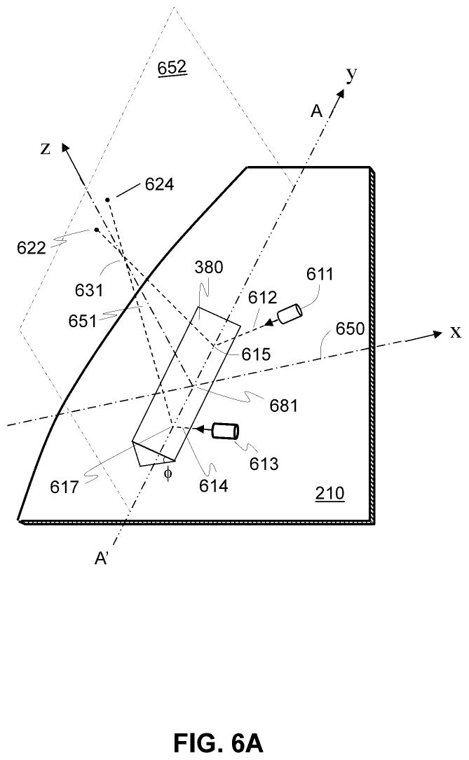

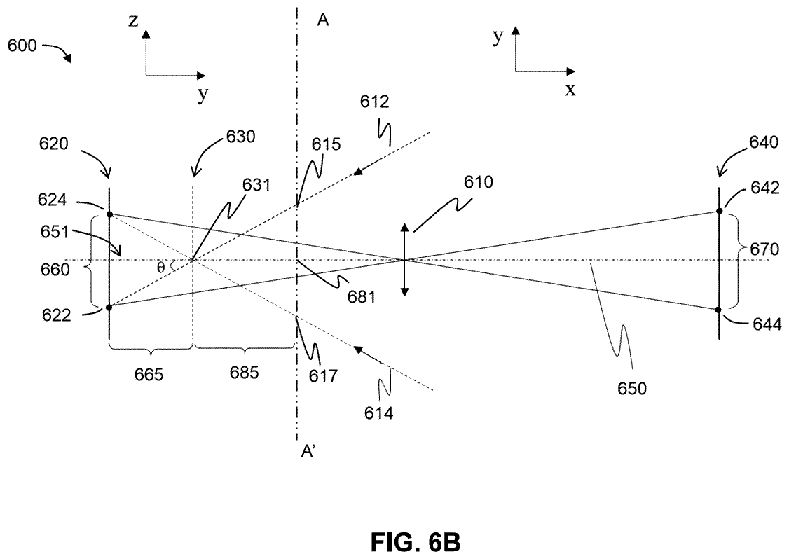

FIG. 6A is a perspective view of a portion of assembly 220. The assembly has a main axis 650, which defines the center of symmetry of the assembly and lies along the x-direction. The main axis 650 can be viewed as a virtual beam which intersects with the beam deflector 380, which is placed along the line AA′ at y direction, at location 681. In one embodiment, the surface of the deflector 681 has a 45° rotation angle (ϕ) around y-axis and it deflects the main axis in z-direction (651). A first and second projector 611 and 613 are placed on the workpiece 210 and project beam 612 and 614 to intersect with the deflector at location 615 and 617 respectively. The deflected beams intersect with each other at location 631 which also intersects with the z axis (651). The projected paths of beams 612 and 614 eventually intersect the surface of the showerhead, forming beam spots 622 and 624, respectively.

FIG. 6B folds portion 652 of the y-z plane at the AA′ line onto the x-y plane for facilitating analysis of beam paths on a flat surface. As shown in FIG. 3B, on the right side of the AA′ line, the main axis 650 is directed along a first direction (x-axis), approximately parallel to the surface of the workpiece 210. On the left side of the AA′ line, the main axis 651 continues on y-z plane, and intersects the showerhead surface 620. The projector projects an electromagnetic beam 612 and 614 onto the deflector 380 at location 615 and 617 respectively, and the beam continues its path on y-z plane. The beams intersect with the main axis 651 at location 631 on a reference plane 630, and produces the beam spot 622 and 624 on the surface of the showerhead 620 respectively. The distance 665, d₆₆₅, from the showerhead surface 620 to the reference plane 630 along x-axis is proportional to d₆₆₀ which is the separation between the beam spot 622 and 624:

$${d}_{665} = \frac{{d}_{660}}{2} \times cot θ ,$$

where θ is the angle between the main axis 650 and the incident beam 612 or 614. cot θ can be obtained by a calibration from a set of known d₆₆₅ and d₆₆₀. In one embodiment, the angle, θ, can be configured as 45°. Under this condition, d₆₆₅=(d₆₆₀)/2.

As shown in FIG. 6B, the low-profile assembly 600 further comprises a focusing element 610, such as a focusing lens, centered on the main axis for focusing the reflected beams of the spot 622 and 624 from the object surface, and forming images of the spot 642 and 644 on an image plane 640. The separation 670, d₆₇₀, between the image spot 642 and 644 on y-axis is proportional to the separation 660, d₆₆₀, and in turn is proportional to the distance 665, d_{swh}. Therefore, d_{swh} can be determined according to d₆₇₀.

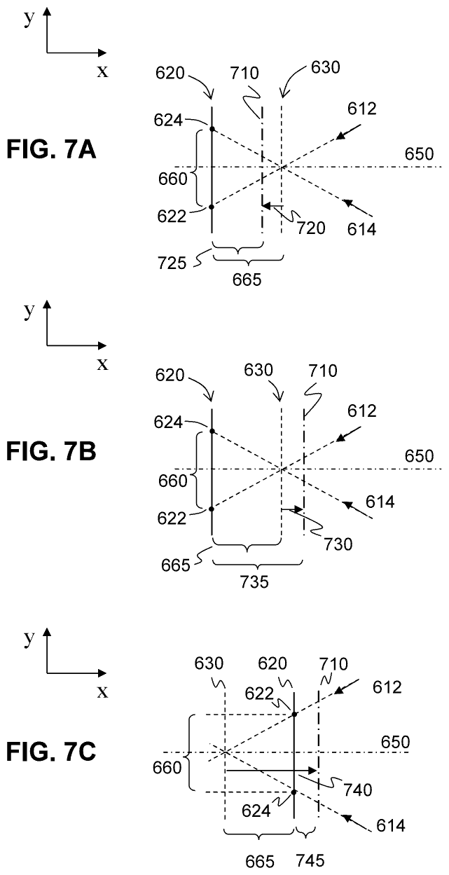

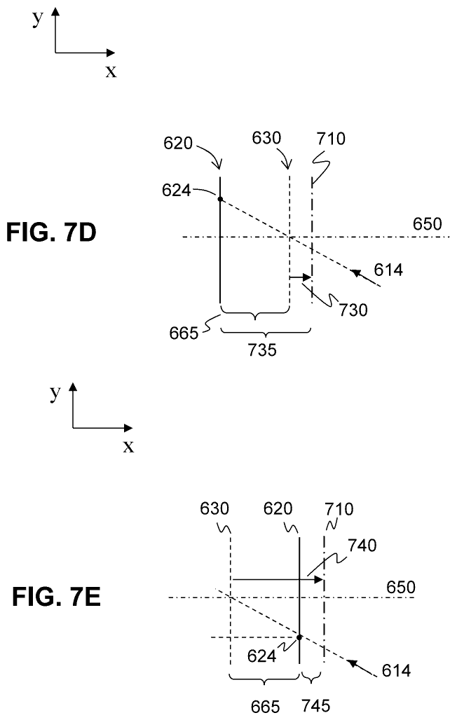

FIGS. 7A-7E further illustrate various relationships between the showerhead surface 620, reference plane 630, and the surface of the workpiece 710 for the assembly 600 shown in FIG. 6B. Shown in FIG. 7A, beam 614 and 614 cross the main axis 650 before intersecting deflector 380. The distance 665, d_{swh} from the showerhead surface 620 to the reference plane 630 along the x-axis can be calculated according to the separation 660, d₆₆₀. Since the reference plane 630 is on right side of the showerhead surface 620, and the distance, d_{swh}, in formular (1) is positive. The surface of the workpiece 710 of the wafer is located on the left side of the reference plane 630, and the distance 720, d_{ref}, is negative. According to formular (1), the gap 725 between the surface of the workpiece and the showerhead surface equals to the value of |d_{swh}|−|d_{ref}|.

Referring now to FIGS. 7B and 7C, in both cases, beams 614 and 616 cross the main axis 650 after intersecting deflector 380. In FIG. 7C, the reference plane 630 is located further beyond the showerhead surface 620. In contrast, in FIG. 7B, the gap 735 is equal to |dswh|+|dref|, while in FIG. 7C, the gap 745 is |dref|−|dswh|. Despite these differences, the separation 660 between beam spots 622 and 624 remains the same in both configurations. However, unlike the single-beam case illustrated in FIG. 4C, it is not possible to determine whether the reference plane 630 lies to the left or right of the object surface 620 solely based on the positions of beam spots 622 and 624.

One solution for avoiding the issue about sign of the distance, d_{swh}, is to arrange the beam 614 and 614 cross the main axis 650 before intersecting deflector 380, as shown in FIG. 7A. Under this condition, the reference plane 630 has to be on the right side of the showerhead surface (i.e. d_{swh}>0).

Another solution to detect the sign of the reference distance, d_{swh}, is to momentarily block or shut off one of the two incident beams. As shown in FIG. 7D and FIG. 7E, beam 612 is momentarily blocked, and there is only one beam spot 624 from beam 614 formed on the showerhead surface 620 for a moment. In FIG. 7D, when the reference plan 630 is on the right side of the object surface 720, the beam spot is above the main axis 750 as in y-direction, and the reference distance 665, d_{swh} is positive. Referring back to FIG. 7B, the gap 735 between the surface of the wafer and the showerhead surface equals to |d_{swh}|+|d_{ref}|.

In FIG. 7E, when the reference plan 630 is on the left side of the object surface 620, the beam spot is below the main axis 650 as in the y-direction, if beam 612 is momentarily blocked. Therefore, d_{swh} is negative, and the gap 745 between the surface of the wafer and the showerhead surface equals to |d_{ref}|−|d_{swh}|.

Under the condition that the reference plane 630 is at the surface 710 of the wafer, i.e. the reference point overlaps with the deflection point, gap=d_{swh}.

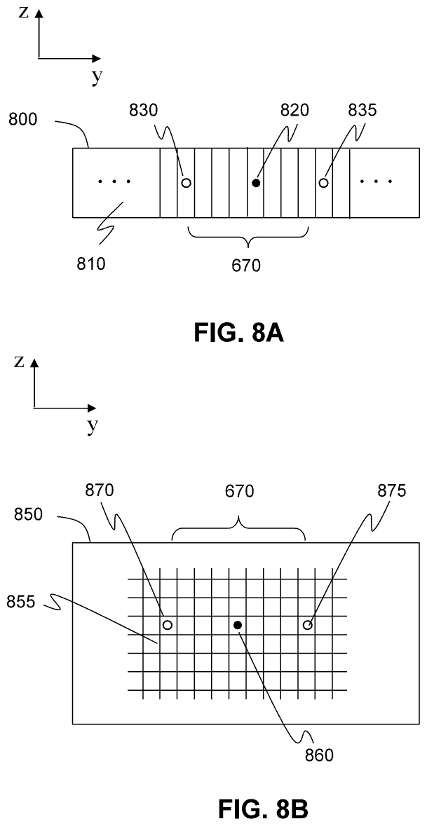

Referring now to FIGS. 8A and 8B, in view of FIG. 6B, assembly 600 includes an imaging sensor array placed at the image plane 640 (y-z plane). FIG. 8A shows a linear imaging sensor array 800, comprising a plurality of imaging pixels 810 arranged in y-direction. FIG. 8B shows a 2-dimensional imaging sensor array 850, comprising a plurality of imaging pixels 855 arranged in z- and y-direction. The main axis 650 of assembly 700 intersects the image array 800 or 850 at location 820 or 860 respectively. In FIG. 8A, the image spots 642 and 644 (of the FIG. 6B) are detected by the imaging sensor array at location 830 and 835 respectively. In FIG. 8B the image spots 642 and 644 are detected by the imaging sensor array at location 870 and 875 respectively. The distance between location 830 and 835 or between 870 and 875 corresponds to the distance 670, which is proportional to the value of d_{swh}. As described above, the sign of the distance, d_{swh}, can be determined by temporarily blocking one of the beams and detecting the position of remaining image spot on the image plane. Using the relative position of the image spot against location of 820 or 860, the sign of d_{swh} can be determined. Alternatively, the surface position of the workpiece can be arranged to be between the showerhead and the reference plane to ensure that gap=|d_{swh}|−|d_{ref}|.

Various types of commercially available image sensor can be used for imaging sensor array 500, 550, 800, or 850. Some examples include charge-coupled device (CCD) sensors, complementary metal-oxide-semiconductor sensors (CMOS), amorphous silicon sensing matrix, and infrared thermal imaging array. The accuracy of a measurement depends on both image array pixel resolution and beam path arrangement. These image sensors are well known to those skilled in the art of image sensing applications and need not be described in more detail herein.

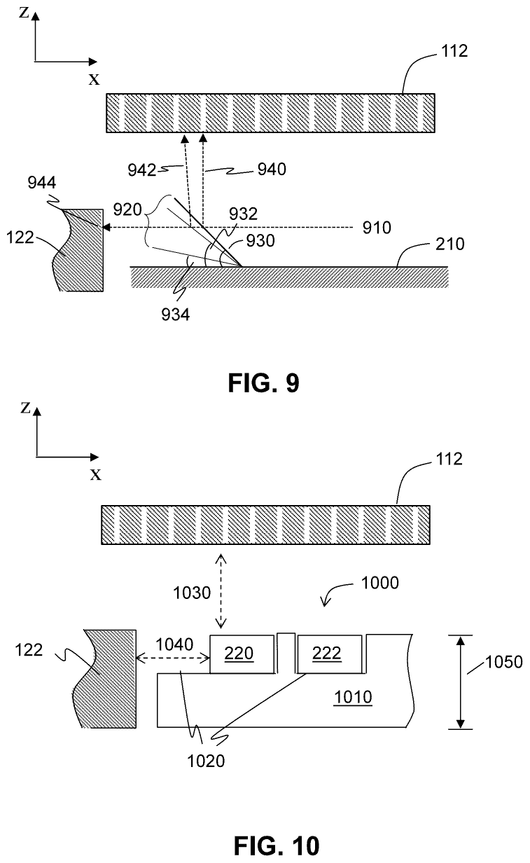

According to some embodiments of the present invention, the beam deflector 380 can take various forms to serve different purposes. FIG. 9 illustrates several examples of beam deflectors and their corresponding applications.

For fixed-beam applications, a wedge prism or a mirror 920 mounted at a 45° angle (930) can be used to deflect the beam 910 by 90°, redirecting it along the z-axis. However, a 90° deflection is not always desirable. For instance, a beam 940 deflected by 90° may intersect with a gas delivery hole on the showerhead, leading to unwanted reflections. In such cases, it is preferable to use a reflector with an appropriate deflection angle 932 to avoid interference with the holes in the showerhead.

According to some embodiments of the present invention, the deflector 380 can be adjustable for dynamic applications. For example, the reflector 920 may be electronically adjusted to deflect beam 910 toward 942 in order to measure the distance between the surface of the showerhead 112 and the surface of the workpiece 210. After this measurement, the deflector can be re-adjusted to a smaller angle 934, allowing beam 910 to pass through and target the side of the focusing ring 122. In this configuration, the assembly 220 can be used to measure the gap between the edge of the workpiece and the inner surface of the focusing ring, thereby verifying that the wafer is concentric with the focusing ring. Techniques for measuring the position of a nearby object along the x-axis without a deflector are fully described in U.S. patent application Ser. No. 18/767,392 and U.S. patent application Ser. No. 19/228,685, the entire contents of which are incorporated herein by reference.

Various types of known optical beam deflectors can be used as the adjustable deflector 380. For example, an electro-optic deflector steers the beam by altering the refractive index of a crystal through the application of an electric field. Alternatively, micro-electro-mechanical systems (MEMS) mirrors can be tilted by applying varying electrical voltages. Another option is a liquid crystal beam deflector, which uses voltage-controlled birefringence in liquid crystals to redirect the beam. These types of adjustable beam deflectors are well-established in the field and will not be discussed further here.

In an alternative embodiment, the deflector can be a combination of a prism and an adjustable mirror for an extended range of the adjustment of the beam direction.

In another embodiment, a wafer with recessed pockets is used as the workpiece to further reduce the overall system 1000 height in the Z-direction. Referring to FIGS. 10, the workpiece compresses a silicon wafer 1010 with recessed pockets 1020. At least one assembly 220 and the control unit 222 can be arranged within the recessed pockets while maintaining the projected electromagnetic beam 1030 or 1040 to intersect with the surface of showerhead 112 or side wall of the focusing ring 122 respectively. In this arrangement, the overall system height 1050 is further minimized.

While examples and variations have been presented in the foregoing description, it should be understood that a vast number of variations exist, and these examples are merely representative, and are not intended to limit the scope, applicability or configuration of the disclosure in any way. Various of the above-disclosed and other features and functions, or alternative thereof, may be desirably combined into many other different systems or applications. Various presently unforeseen or unanticipated alternatives, modifications variations, or improvements therein or thereon may be subsequently made by those skilled in the art which are also intended to be encompassed by the claims, below.

1. A system for contactless object measurement comprising: a workpiece, at least one assembly, and a central control unit; wherein the central control unit comprises a power source and an image processor; the assembly and the control unit are attached on a surface of the workpiece; the assembly comprises:
a main axis directed to a first direction and approximately parallel to the surface of the workpiece to intersect a deflector which is mounted on the workpiece and along the second direction; the deflected portion of the main axis intersects with an object in the third direction;
a projector mounted on the workpiece for projecting an electromagnetic beam toward the deflector, wherein the beam is configured to intersect with the main axis at a reference plane either before or after the deflection; the projection of the beam produces a beam spot on a surface of an object; the separation between the spot and the main axis along a second direction is proportional to the distance from the surface of the object to the reference plane;
a focusing element centered on the main axis for focusing the reflected beam of the spot from the object surface, and forming an image of the spot on an image plane;
an imaging sensor array placed at the image plane and coupled with the image processor in the control unit for determining the position of the image of the spot on the image plane; and
wherein the entire system is configured to have a low profile, with an overall height of less than 10 mm in the third direction.

2. The system of claim 1, wherein the deflection angle of the deflector is adjustable to deflect the beam to a desired direction.

3. The system of claim 1, wherein at least three of the assemblies are attached on the workpiece and are aligned their main axis to different directions to detect the gap between the surface of the workpiece and the surface of the object in the third direction at different positions on the workpiece.

4. The system of claim 1, wherein the height of the low profile is within 4 mm, and the diameter of the beam spot is smaller than 1 mm.

5. The system of claim 1, wherein the workpiece is a wafer or wafer-like substrate.

6. The system of claim 1, wherein the workpiece is a wafer having a recessed portion to host the assembly and the control unit.

7. The system of claim 1, wherein the electromagnetic beam is characterized by a wavelength spectrum selected from visible light, microwave, infrared light, and ultraviolet light.

8. The system of claim 1, wherein the imaging sensor array is selected from CCD, CMOS, amorphous silicon sensing matrix, and infrared thermal imaging array.

9. The system of claim 1, wherein the projector is made of a light source coupled to an optical fiber.

10. The system of claim 1, wherein the image sensor detects an image spot on an image plane and determines the distance, d_{swh}, from the object surface to the reference plane, according to the distance from the image spot to the main axis intersect with the image plane in the second direction, wherein the gap between the surface of the workpiece and the surface of the object in the third direction is determined according to the equation:
gap=d_{swh}+d_{ref}, wherein d_{ref} is the distance from the reference plane to the surface of the workpiece.

11. A system for contactless object measurement comprising: a workpiece, at least one assembly, and a central control unit; wherein the central control unit comprises a power source and an image processor; the assembly and the control unit are attached on a surface of the workpiece; the assembly comprises:
a main axis directed to a first direction and approximately parallel to the surface of the workpiece to intersect a deflector which is mounted on the workpiece and along the second direction; the deflected portion of the main axis intersects with an object in the third direction;
a first and a second projectors mounted on the workpiece for projecting electromagnetic beams toward the deflector, wherein the first and the second beams are configured to be symmetrical about the main axis and to intersect with each other at a reference plane either before or after the deflection; the deflected first and second beams produce a first and second beam spots on the surface of an object; the separation between the first and second beam spot along a second direction is proportional to the distance from the surface of the object to the reference plane;
a focusing element centered on the main axis for focusing the reflected beams of the first and the second spots from the object surface, and forming images of the spots on an image plane;
an imaging sensor array placed at the image plane and coupled with the image processor in the control unit for determining the position of the images of the spots on the image plane; and
wherein the entire system is configured to have a low profile, with an overall height of less than 10 mm in the third direction.

12. The system of claim 11, the first and the second beams are operated together to determine the distance, d_{swh}, from the object surface to the reference plane.

13. The system of claim 11, wherein the deflector is positioned between the reference point and the surface of the object along the main axis.

14. The system of claim 11, wherein the deflector is positioned at the reference point on the main axis.

15. The system of claim 11, one of the first and the second beams is operated alone momentarily to determine the sign of d_{swh}.

16. The system of claim 11, wherein the deflection angle of the deflector is adjustable to deflect the beams to desired directions.

17. The system of claim 11, wherein at least three of the assemblies are attached on the workpiece and are aligned their main axis to different directions to detect the gap between the surface of the workpiece and the surface of the object in the third direction at different positions on the workpiece.

18. The system of claim 11, wherein the height of the low profile is within 4 mm, and the diameter of the beam spot is smaller than 1 mm.

19. The system of claim 11, wherein the workpiece is a wafer or wafer-like substrate.

20. The system of claim 11, wherein the workpiece is a wafer having a recessed portion to host the assembly and the control unit.

21. The system of claim 11, wherein the electromagnetic beam is characterized by a wavelength spectrum selected from visible light, microwave, infrared light, and ultraviolet light.

22. The system of claim 11, wherein the imaging sensor array is selected from CCD, CMOS, amorphous silicon sensing matrix, and infrared thermal imaging array.

23. The system of claim 11, wherein the projector is made of a light source coupled to an optical fiber.

24. The system of claim 11, wherein the image sensor detects the image spots on the image plane and determines the distance, d_{swh}, from the object surface to the reference plane, according to the distance between the first and the second image spot on the image plane in the second direction, wherein the gap between the surface of the workpiece and the surface of the object in the third direction is determined according to the equation: gap=d_{swh}+d_{ref}, wherein d_{ref} is the distance from the reference plane to the surface of the workpiece.
